(19) United States
(12) Patent Application Publication
(10) Pub. No.: US 2019/0043768 A1
(43) Pub. Date: Feb. 7, 2019

(54) Methods for Fabricating Semiconductor Devices Using a Fringe Signal

(71) Applicant: Samsung Electronics Co., Ltd., Suwon-si (KR)

(72) Inventors: Se Jin Oh, Hwaseong-si (KR); Yu Sin Kim, Hwaseong-si (KR); Jae Woo Kim, Hwaseong-si (KR); Jin Young Bang, Hwaseong-si (KR); Doug Yong Sung, Seoul (KR); In Yong Hwang, Suwon-si (KR)

(21) Appl. No.: 15/895,208

(22) Filed: Feb. 13, 2018

(30) Foreign Application Priority Data
Aug. 3, 2017 (KR) 10-2017-0098469

(51) Int. Cl. H01L 21/66; H01L 21/027; H01L 21/02; H01L 21/311; H01L 21/768; G03F 7/09

(52) U.S. Cl. CPC H01L 22/26; H01L 21/0273; H01L 21/0217; H01L 21/02164; H01L 27/105; H01L 21/31116; H01L 21/31144; H01L 21/76816; G03F 7/094; H01L 21/022

(57) ABSTRACT

Methods for fabricating semiconductor devices are provided including forming a stacked structure including a first mold layer and a second mold layer on a substrate; forming a first photoresist pattern on the stacked structure; etching the second mold layer using the first photoresist pattern as a mask; forming a second photoresist pattern by etching a portion of the first photoresist pattern; measuring a first fringe signal generated by an interference phenomenon between first reflected lights reflected from the first photoresist pattern; forming a stepped structure by etching the second mold layer and the first mold layer which is exposed, using the second photoresist pattern as a mask; measuring a second fringe signal generated by an interference phenomenon between second reflected lights reflected from the second mold layer; calculating a third fringe signal by summing the first fringe signal and the second fringe signal; calculating and a first etch rate of an upper surface of the first photoresist pattern using the third fringe signal; calculating a second etch rate of a side surface of the first photoresist pattern using the first etch rate; and controlling a degree of etching the side surface of the second photoresist pattern using the second etch rate.

### CLAIM OF PRIORITY

This application claims priority to Korean Patent Application No. 10-2017-0098469 filed on Aug. 3, 2017 in the Korean Intellectual Property Office, the disclosure of which is hereby incorporated herein by reference in its entirety.

### FIELD

The inventive concept relates generally to semiconductor devices and, more particularly, to methods of fabricating semiconductor devices using a fringe signal.

### BACKGROUND

A volatile memory device loses stored data when power is removed or lost. Volatile memory devices generally include static random access memory (SRAM), dynamic RAM (DRAM), synchronous DRAM (SDRAM), and the like. A nonvolatile memory device retains stored data even when power is removed or turned off. Nonvolatile memory devices general include flash memory devices, read only memory (ROM), programmable ROM (PROM), electrically programmable ROM (EPROM), electrically erasable and programmable ROM (EEPROM), resistive memory device, for example, phase-change RAM (PRAM), ferroelectric RAM (FRAM), resistive RAM (RRAM)), and the like.

Integration density of the nonvolatile memory devices keeps increasing in order to meet customer demands for better performance and lower cost. However, for the two-dimensional or planar memory device, the integration density is determined by the area occupied by the unit memory cells. Therefore, in recent years, three-dimensional (3D) memory device with vertical arrangement of unit memory cells has been developed.

### SUMMARY

Some embodiments of the present inventive concept provide methods of fabricating a semiconductor device, which forms a mold layer having a stepped structure by controlling the degree of etching of side surfaces of a photoresist pattern using a fringe signal measurement.

In some embodiments of the present inventive concept, a method for fabricating a semiconductor device is provided including forming a stacked structure, wherein the stacked structure comprises a first mold layer and a second mold layer sequentially stacked on a substrate, forming a first photoresist pattern on the stacked structure, etching the second mold layer using the first photoresist pattern as a mask, forming a second photoresist pattern by etching a portion of the first photoresist pattern, measuring a first fringe signal generated by an interference phenomenon between first reflected lights reflected from the first photoresist pattern, forming a stepped structure by etching the second mold layer and the first mold layer which is exposed, using the second photoresist pattern as a mask, measuring a second fringe signal generated by an interference phenomenon between second reflected lights reflected from the second mold layer, calculating a third fringe signal by summing the first fringe signal and the second fringe signal, calculating a first etch rate of an upper surface of the first photoresist pattern using the third fringe signal, calculating a second etch rate of a side surface of the first photoresist pattern using the first etch rate, and controlling a degree of etching the side surface of the second photoresist pattern using the second etch rate.

In further embodiments of the present inventive concept, methods for fabricating a semiconductor device are providing including providing a substrate comprising a first region, a second region and a third region, forming a stacked structure, wherein the stacked structure comprises a first mold layer and a second mold layer sequentially stacked on the substrate, forming a photoresist pattern on the stacked structure to overlap the first region and the second region, etching the second mold layer formed on the third region using the photoresist pattern as a mask, etching a portion of an upper surface of the photoresist pattern and the photoresist pattern overlapping the second region, measuring a first signal using first reflected light reflected from the upper surface of the photoresist pattern while the portion of the upper surface of the photoresist pattern is being etched, etching the second mold layer formed on the second region and the first mold layer formed on the third region, using the etched photoresist pattern overlapping the first region as a mask, measuring a second signal using second reflected light reflected from the second mold layer while the second mold layer formed on the second region is being etched, calculating a third signal by summing the first signal and the second signal, calculating a first etch rate of the upper surface of the photoresist pattern using the third signal, calculating a second etch rate of a side surface of the photoresist pattern using the first etch rate, and controlling a degree of etching the side surface of the second photoresist pattern using the second etch rate.

In still further embodiments of the present inventive concept, methods for fabricating a semiconductor device are provided including forming a stacked structure, wherein the stacked structure comprises a first mold layer, a second mold layer, and a third mold layer sequentially stacked on a substrate, forming a first photoresist pattern on the stacked structure, etching the third mold layer using the first photoresist pattern as a mask, forming a second photoresist pattern by etching a portion of an upper surface and a portion of a side surface of the first photoresist pattern, measuring a first fringe signal generated by an interference phenomenon between first reflected lights reflected from the upper surface of the first photoresist pattern while forming the second photoresist pattern, forming a stepped structure by etching the third mold layer and the second mold layer which is exposed, using the second photoresist pattern as a mask, measuring a second fringe signal generated by an interference phenomenon between second reflected lights reflected from the third mold layer while the third mold layer is being etched, calculating a third fringe signal by summing the first fringe signal and the second fringe signal, calculating a first etch rate of the upper surface of the first photoresist pattern using the third fringe signal, calculating a second etch rate of the side surface of the first photoresist pattern using the first etch rate, forming a third photoresist pattern by etching a portion of the upper surface and a portion of the side surface of the second photoresist pattern using the first etch rate and the second etch rate, and forming a stepped structure by etching the third mold layer, the second mold layer which is exposed, and the first mold layer which is exposed, using the third photoresist pattern.

### BRIEF DESCRIPTION OF THE DRAWINGS

The above and other embodiments, features and advantages of the present inventive concept will become more apparent to those of ordinary skill in the art by describing in detail embodiments thereof with reference to the accompanying drawings, in which:

FIG. 1 is a flowchart illustrating processing steps in the fabrication of semiconductor devices in accordance with some embodiments of the present inventive concept.

FIGS. 2 through 5, FIG. 7, FIG. 9 and FIG. 10 are cross sections illustrating processing steps in the fabrication of semiconductor devices in accordance with some embodiments of the present inventive concept.

FIG. 6 is a graph illustrating fringe signals measured during etching of the photoresist pattern shown in FIG. 5 in accordance with some embodiments of the present inventive concept.

FIG. 8 is a graph illustrating the fringe signal measured during etching of the mold film shown in FIG. 7 in accordance with some embodiments of the present inventive concept.

FIGS. 11 through 14 are cross sections illustrating processing steps in the fabrication of semiconductor devices in accordance with some embodiments of the present inventive concept.

### DETAILED DESCRIPTION

Specific embodiments of the inventive concept now will be described with reference to the accompanying drawings. This inventive concept may, however, be embodied in many different forms and should not be construed as limited to the embodiments set forth herein; rather, these embodiments are provided so that this disclosure will be thorough and complete, and will fully convey the scope of the inventive concept to those skilled in the art. In the drawings, like numbers refer to like elements. It will be understood that when an element is referred to as being “connected” or “coupled” to another element, it can be directly connected or coupled to the other element or intervening elements may be present. As used herein the term “and/or” includes any and all combinations of one or more of the associated listed items.

The terminology used herein is for the purpose of describing particular embodiments only and is not intended to be limiting of the inventive concept. As used herein, the singular forms “a”, “an” and “the” are intended to include the plural forms as well, unless expressly stated otherwise. It will be further understood that the terms “includes,” “comprises,” “including” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the specification and the relevant art and will not be interpreted in an idealized or overly formal sense unless expressly so defined herein.

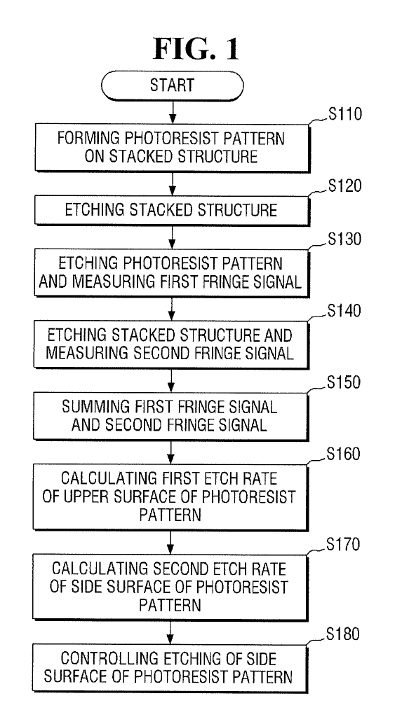

Methods for fabricating semiconductor devices according to some embodiments of the present inventive concept will be discussed with respect to FIGS. 1 through 10.

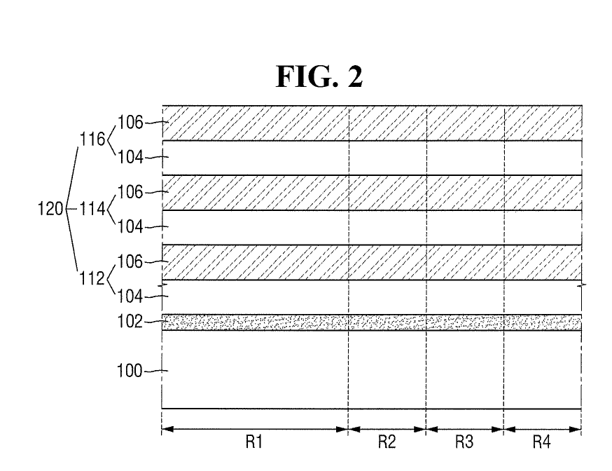

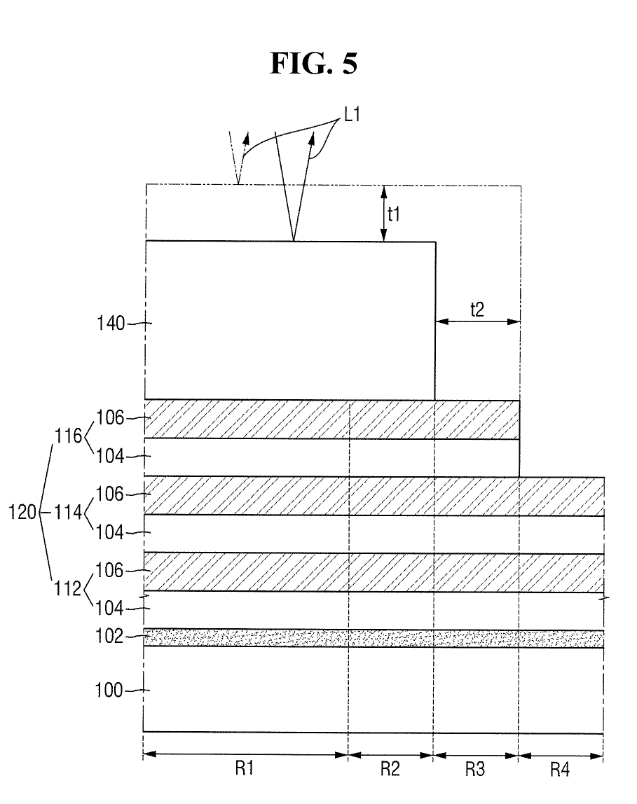

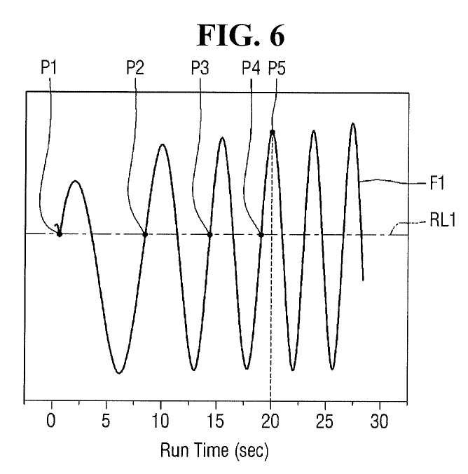

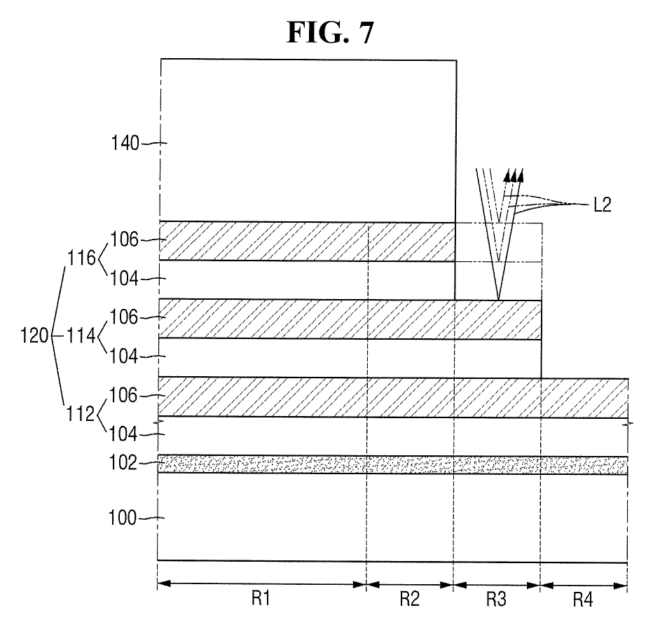

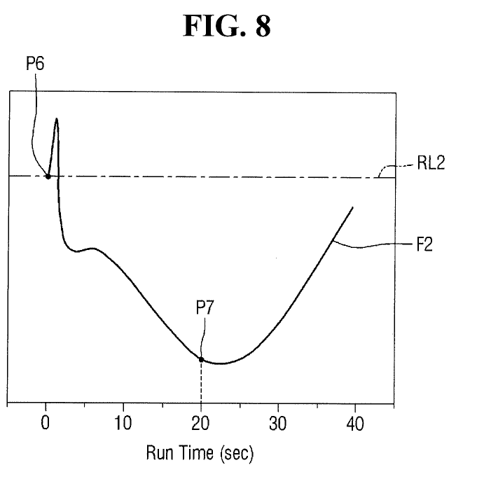

FIG. 1 is a flowchart illustrating processing steps in the fabrication of semiconductor devices in accordance with some embodiments of the present inventive concept. FIGS. 2 through FIG. 7, FIG. 9 and FIG. 10 are cross sections illustrating intermediate steps in the fabrication of semiconductor devices in accordance with some embodiments of the present inventive concept. FIG. 6 is a graph illustrating fringe signals measured during etching of the photoresist pattern shown in FIG. 5. FIG. 8 is a graph illustrating the fringe signal measured during etching of the mold film shown in FIG. 7.

By way of example, embodiments will be described herein with reference to an etching process for forming a word line pad having a stepped structure in a vertical NAND flash memory fabrication process. However, embodiments of the present inventive concept are not limited thereto. For example, in some embodiments, a method for fabricating a semiconductor device according to the present inventive concept may also be used for forming a structure having a stepped structure in the manufacturing processes of any of a planar NAND flash memory, a PRAM memory, or a DRAM memory.

Referring first to FIGS. 1 through 3, operations begin at block S110 by forming a first photoresist pattern 130 on a stacked structure 120. In particular, an impurity region 102 may be formed on the substrate 100, in which the substrate 100 includes a first region R1, a second region R2, a third region R3, and a fourth region R4 formed sequentially adjacent to each other. The stacked structure 120 may then be formed, having a first mold layer 112, a second mold layer 114 and a third mold layer 116 sequentially stacked on the impurity region 102. However, embodiments of the present inventive concept are not limited thereto. For example, in some embodiments, the impurity region 102 may be omitted.

The stacked structure 120 may include a first sacrificial layer 104 and a second sacrificial layer 106 alternately stacked on the substrate 100. In these embodiments, each of the first mold layer 112, the second mold layer 114 and the third mold layer 116 may include one first sacrificial layer 104 and one second sacrificial layer 106.

While FIG. 2 illustrates the second sacrificial layer 106 positioned on the uppermost layer of the stacked structure 120 and the first sacrificial layer 104 positioned on the lowermost layer of the stacked structure 120, embodiments of the present inventive concept are not limited thereto. For example, in some embodiments, the first sacrificial layer 104 may be positioned on the uppermost layer of the stacked structure 120 without departing from the scope of the present inventive concept.

While FIG. 2 illustrates that the stacked structure 120 includes the first to third mold layers 112, 114, and 116, embodiments of the present inventive concept are not limited thereto. For example, in some embodiments, the number of mold layers included in the stacked structure 120 may vary depending on the memory capacity of the semiconductor device.

The first sacrificial layer 104 may be formed of a material having an etch selectivity to the second sacrificial layer 106. The first sacrificial layer 104 may include silicon nitride and the second sacrificial layer 106 may include silicon oxide. However, embodiments of the present inventive concept are not limited thereto. For example, in some embodiments, the first sacrificial layer 104 and the second sacrificial layer 106 may respectively include films made from silicon oxides having different etch rate from each other.

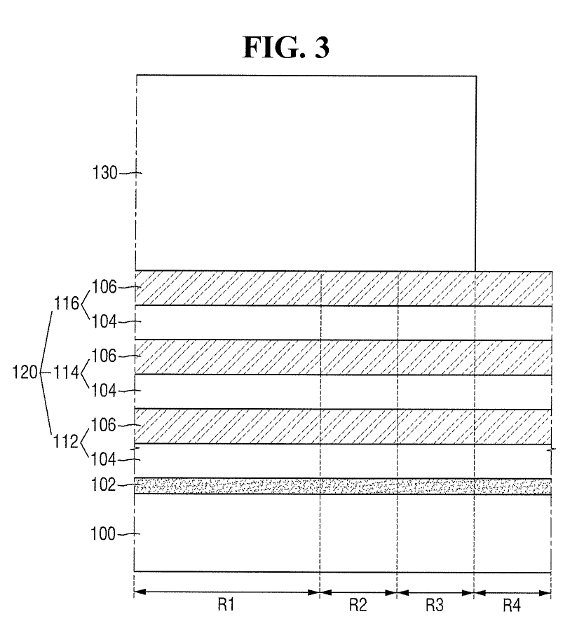

Referring to FIG. 3, a first photoresist pattern 130 is formed on the stacked structure 120. In particular, the first photoresist pattern 130 may be formed on the stacked structure 120 overlapping the first through third regions R1, R2, and R3 of the substrate 100.

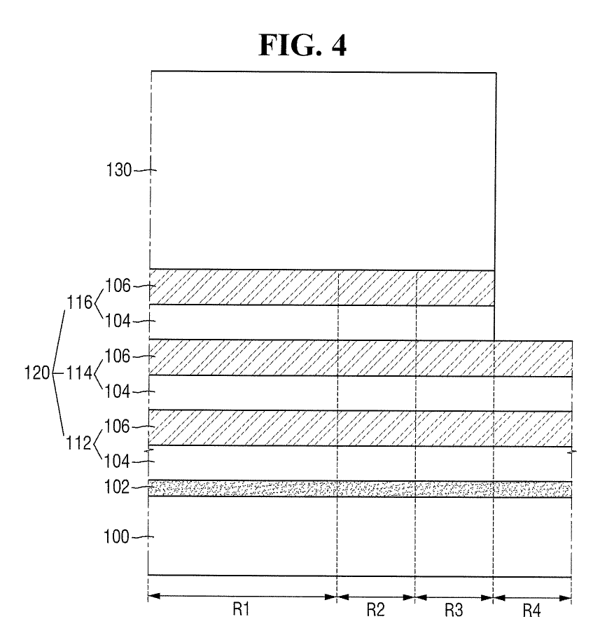

Referring to FIGS. 1 and 4, using the first photoresist pattern 130 as a mask, a portion of the stacked structure 120 is etched (block S120). In particular, the third mold layer 116 overlapping the fourth region R4 of the substrate 100 may be etched using the first photoresist pattern 130 as a mask. This may result in exposure of the upper surface of the second mold layer 114 of the stacked structure 120 formed on the fourth region R4 of the substrate 100.

Referring to FIGS. 1, 5 and 6, during etching of the portion of the first photoresist pattern 130 (FIG. 4), a first signal is measured using first reflected lights L1 reflected from the first photoresist pattern 130 (FIG. 4) (block S130). It will be described herein by way of example that the first signal is a fringe signal (hereinafter, “first fringe signal F1”). However, embodiments of the present inventive concept are not limited thereto.

A second photoresist pattern 140 may be formed by etching a portion of the upper surface and a portion of the side surface of the first photoresist pattern 130 (FIG. 4) using plasma. The second photoresist pattern 140 may be formed so as to overlap the first and second regions R1 and R2 of the substrate 100.

For example, a side portion of the first photoresist pattern 130 (FIG. 4) overlapping the third region R3 of the substrate 100 may be etched. This may result in exposure of the upper surface of the third mold layer 116 of the stacked structure 120 formed on the third region R3 of the substrate 100.

A first etched thickness t1 of the upper surface of the first photoresist pattern 130 (FIG. 4) may be less than a second etched thickness t2 of the side surface of the first photoresist pattern 130 (FIG. 4). In these embodiments, the ratio of the first etched thickness t1 to the second etched thickness t2 may be 0.8, for example. However, embodiments of the present inventive concept are not limited thereto. For example, in some embodiments, the ratio of the first etched thickness t1 to the second etched thickness t2 may be determined differently.

While FIG. 5 illustrates that the first etched thickness t1 is less than the second etched thickness t2, embodiments of the present inventive concept are not limited thereto. For example, in some embodiments, the first etched thickness t1 may be equal to the second etched thickness t2. Furthermore, in some embodiments, the first etched thickness t1 may be greater than the second etched thickness t2. However, even in these embodiments, the ratio of the first etched thickness t1 to the second etched thickness t2 may be kept constant in the subsequent process.

During etching of the portion of the upper surface and the portion of the side surface of the first photoresist pattern 130 (FIG. 4), light may be irradiated onto the upper surface of the first photoresist pattern 130 (FIG. 4) in real time, and a first fringe signal F1 may be measured as it F1 is generated by the interference phenomenon between the first reflected lights L1 reflected from the upper surface of the first photoresist pattern 130 (FIG. 4).

Measuring the first fringe signal F1 may be performed simultaneously during the etching of the portion of the upper surface and the portion of the side surface of the first photoresist pattern 130 (FIG. 4). However, embodiments of the present inventive concept are not limited thereto. For example, in some embodiments, measuring the first fringe signal F1 may be performed after a predetermined time interval from the etching of the portion of the upper surface and the portion of the side surface of the first photoresist pattern 130 (FIG. 4).

Referring to FIG. 6, the first fringe signal F1 may be convex upward on the graph based on the first reference line RL1, when constructive interference occurs between the first reflected lights L1. Furthermore, the first fringe signal F1 may be convex downward on the graph based on the first reference line RL1, when destructive interference occurs between the first reflected lights L1.

Occurrence of one constructive interference and one destructive interference between the first reflected lights L1 may be defined as one cycle of the first fringe signal F1. For example, as shown in FIG. 6, one cycle may be formed between a first position P1 at which the first photoresist pattern 130 (FIG. 4) begins to be etched, and a second position P2 which is after one constructive interference and one destructive interference are occurred respectively. Likewise, one cycle may be formed between the second position P2 and a third position P3, and one cycle may be formed between the third position P3 to the fourth position P4.

For example, in FIG. 6, it is understandable that the number of cycles of the first fringe signal F1 is about 3.25 at a 20 second point in the etching process time, as counted from the first position P1, at which the first photoresist pattern 130 (FIG. 4) begins to be etched, to the fifth position P5, i.e., to the 20 second point.

Some embodiments of the present inventive concept can calculate a third fringe signal using the number of cycles of the first fringe signal F1 according to the etching process time. These embodiments will be discussed further herein.

Referring to FIG. 1, FIG. 7 and FIG. 8, while a portion of the stacked structure 120 is being etched, a second signal is measured using the second reflected lights L2 reflected from the stacked structure 120 (block S140). It is discussed herein by way of example that the second signal is a fringe signal (hereinafter, “second fringe signal F2”). However, embodiments of the present inventive concept are not limited thereto.

In particular, using the second photoresist pattern 140 as a mask, the third mold layer 116 overlapping the third region R3 of the substrate 100, and the second mold layer 114 overlapping the fourth region R4 of the substrate 100 may be etched, respectively.

This may result in exposure of the upper surface of the second mold layer 114 on the third region R3 of the substrate 100, and the upper surface of the first mold layer 112 on the fourth region R4 of the substrate 100, respectively. Through this etching process, a stepped structure may be formed.

During etching of the third mold layer 116 overlapping the third region R3 of the substrate 100, light may be irradiated onto the upper surface of the third mold layer 116 in real time, and a second fringe signal F2, which is generated by the interference phenomenon between the second reflected lights L2 reflected from the upper surface of the third mold layer 116, may be measured.

Measuring the second fringe signal F2 may be performed simultaneously during the etching of the third mold layer 116. However, embodiments of the present inventive concept are not limited thereto. For example, in some embodiments, measuring the second fringe signal F2 may be performed after a predetermined time interval from the etching of the third mold layer 116.

Referring to FIG. 8, the second fringe signal F2 may be convex upward on the graph based on the second reference line RL2, when constructive interference occurs between the second reflected lights L2. Furthermore, the second fringe signal F2 may be convex downward on the graph based on the second reference line RL2, when destructive interference occurs between the second reflected lights L2.

Occurrence of one constructive interference and one destructive interference between the second reflected lights L2 may be defined as one cycle of the second fringe signal F2. For example, as shown in FIG. 8, one cycle may be formed between a sixth position P6 at which the third mold layer 116 (FIG. 7) overlapping the third region R3 of the substrate 100 begins to be etched, and a position on the second reference line RL2 which is after one constructive interference and one destructive interference are occurred respectively.

FIG. 8 illustrates that the second fringe signal F2 does not arrive at the position on the second reference line RL2 after occurrence of the destructive interference between the second reflected lights L2. For example, the graph of FIG. 8 shows that the second fringe signal F2 does not form one cycle.

Likewise FIG. 6 that is described above with reference to 20 second point in the etching process time, FIG. 8 will also be described with reference to 20 second point in the etching process time.

For example, in FIG. 8, it is understandable that the number of cycles of the second fringe signal F2 is about 0.7 at the 20 second point in the etching process time, as counted from the sixth position P6, at which the third mold layer 116 (FIG. 7) overlapping the third region R3 of the substrate 100 begins to etched, to the seventh position P7 which is the 20 second point in the etching process time. For example, the number of cycles of the second fringe signal F2 is 0.5 as counted from the sixth position P6 to the point of meeting the second reference line RL2, after occurrence of the constructive interference between the second reflected light L2, and the number of cycles of the second fringe signal F2 is about 0.2 as counted from the point of meeting the second reference line RL2 to the seventh position P7.

Some embodiments of the present inventive concept can calculate a third signal at (block S150), by summing up the number of cycles of the first fringe signal F1 (FIG. 6) according to the etching process time of the first photoresist pattern 130 (FIG. 4) and the number of cycles of the second fringe signal F2 according to the etching process time of the third mold layer 116 (FIG. 7) overlapping the third region F3 of the substrate 100. It is described herein by way of example that the third signal is a fringe signal (hereinafter, “third fringe signal”). However, embodiments of the present inventive concept are not limited thereto.

The number of cycles of the third fringe signal corresponds to a sum of the number of cycles (i.e., 3.25) of the first fringe signal F1 (FIG. 6) at the 20 second point after the start of the etching process of the first photoresist pattern 130 (FIG. 4), and the number of cycles (i.e., 0.7) of the second fringe signal F2 (FIG. 8) at the 20 second point after the start of the etching process of the third mold layer 116 (FIG. 7) overlapping the third region R3 of the substrate 100, as described above with reference to FIG. 6 and FIG. 8 by way of example. For example, the number of cycles of the third fringe signal at the 20 second point after the start of the respective etching processes is the sum of 3.25 and 0.7, that is, 3.95.

A first etch rate of the upper surface of the first photoresist pattern 130 (FIG. 4) is calculated using the calculated number of cycles of the third fringe signal (block S160).

In particular, the first etch rate may be calculated by using a predetermined ratio of a first etched thickness t1 (FIG. 5) of the upper surface of the first photoresist pattern 130 (FIG. 4) to the number of fringe cycles of the third fringe signal.

A second etch rate of the side surface of the first photoresist pattern 130 (FIG. 4) is calculated using the calculated first etch rate (block S170).

In particular, the second etch rate may be calculated by using a predetermined ratio of the first etch rate to the second etch rate. In these embodiments, the first etch rate and the second etch rate may be different from each other. For example, the first etch rate may be less than the second etch rate. In these embodiments, a first etched thickness t1 (FIG. 5) of the upper surface of the first photoresist pattern 130 (FIG. 4) may be less than a second etched thickness t2 (FIG. 5) of the side surface of the first photoresist pattern 130 (FIG. 4).

For example, when the ratio of the first etch rate to the second etch rate is 0.8, the ratio of the first etched thickness t1 (FIG. 5) of the upper surface of the first photoresist pattern 130 (FIG. 4) to the second etched thickness t2 (FIG. 5) of the side surface of the first photoresist pattern 130 (FIG. 4) is 0.8.

Although in embodiments discussed above, the first etch rate and the second etch rate are different from each other, embodiments of the present inventive concept are not limited thereto. Accordingly, in some embodiments, the first etch rate and the second etch rate may be equal to each other without departing from the scope of the present inventive concept.

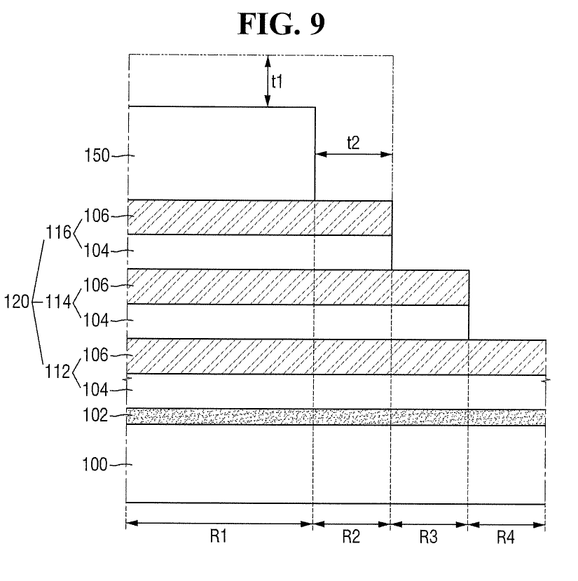

Referring to FIG. 1 and FIG. 9, a degree of etching the side surface of the second photoresist pattern 140 (FIG. 7) may be controlled using the second etch rate (block S180).

In particular, the first etch rate of the upper surface of the first photoresist pattern 130 (FIG. 4) may be calculated using the third fringe signal that is calculated by measuring the first fringe signal F1 (FIG. 6) and the second fringe signal F2 (FIG. 8).

Using the calculated first etch rate, the first etched thickness t1 (FIG. 5) of the upper surface of the first photoresist pattern 130 (FIG. 4) may be adjusted to a desired etched thickness according to the etching process time. In these embodiments, the first etched thickness t1 (FIG. 5) of the upper surface of the first photoresist pattern 130 (FIG. 4) is adjusted in consideration of the second etch rate of the side surface of the first photoresist pattern 130 (FIG. 4).

Accordingly, the second etched thickness t2 (FIG. 5) of the side surface of the first photoresist pattern 130 (FIG. 4) may be precisely controlled using the first fringe signal F1 (FIG. 6) and the second fringe signal F2 (FIG. 8).

Referring to FIG. 9, a third photoresist pattern 150 may be formed by etching a portion of the upper surface and a portion of the side surface of the second photoresist pattern 140 (FIG. 7) using plasma.

For example, the portion of the side surface of the second photoresist pattern 140 (FIG. 7) overlapping the second region R2 of the substrate 100 may be etched. This may result in exposure of the upper surface of the third mold layer 116 of the stacked structure 120 formed on the second region R2 of the substrate 100.

The portion of the upper surface and the portion of the side surface of the second photoresist pattern 140 (FIG. 7) may be etched using the first etch rate of the upper surface of the first photoresist pattern 130 (FIG. 4) and the second etch rate of the side surface of the first photoresist pattern 130 (FIG. 4)

In these embodiments, the first etched thickness t1 (FIG. 5) of the upper surface of the first photoresist pattern 130 (FIG. 4) may be equal to the etched thickness t1 (FIG. 9) of the upper surface of the second photoresist pattern 140 (FIG. 7). Furthermore, the second etched thickness t2 (FIG. 5) of the side surface of the first photoresist pattern 130 (FIG. 4) may be equal to the etched thickness t2 (FIG. 9) of the side surface of the second photoresist pattern 140 (FIG. 7).

This may result in the width of the exposed upper surface of the third mold layer 116 on the second region R2 of the substrate 100 to be equal to the width of the exposed upper surface of the second mold layer 114 on the third region R3 of the substrate 100. For example, the width of the second region R2 of the substrate 100 may be defined to be equal to the width of the third region R3 of the substrate 100.

However, embodiments of the present inventive concept are not limited thereto. For example, in some embodiments, the first etched thickness t1 (FIG. 5) of the upper surface of the first photoresist pattern 130 (FIG. 4) may be different from the etched thickness t1 (FIG. 9) of the upper surface of the second photoresist pattern 140 (FIG. 7). Furthermore, the second etched thickness t2 (FIG. 5) of the side surface of the first photoresist pattern 130 (FIG. 4) may be different from the etched thickness t2 (FIG. 9) of the side surface of the second photoresist pattern 140 (FIG. 7).

This may result in the width of the exposed upper surface of the third mold layer 116 on the second region R2 of the substrate 100 to be different from the width of the exposed upper surface of the second mold layer 114 on the third region R3 of the substrate 100. For example, the width of the second region R2 of the substrate 100 may be defined to be different from the width of the third region R3 of the substrate 100.

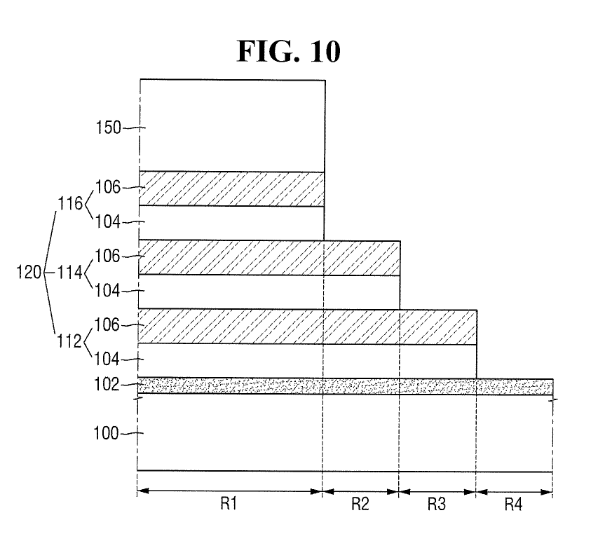

Referring to FIG. 10, using the third photoresist pattern 150 as a mask, the third mold layer 116 overlapping the second region R2 of the substrate 100, the second mold layer 114 overlapping the third region R3 of the substrate 100, and the first mold layer 112 overlapping the fourth region R4 of the substrate 100 may be etched, respectively.

This may result in exposure of the upper surface of the second mold layer 114 on the second region R2 of the substrate 100, the upper surface of the first mold layer 112 on the third region R3 of the substrate 100, and the upper surface of the impurity region 102 on the fourth region R4 of the first region R4, respectively. Through this etching process, a stepped structure may be formed.

Methods for fabricating semiconductor devices according to some embodiments of the present inventive concept are capable of precisely controlling the second etched thickness t2 (FIG. 5) of the side surface of the first photoresist pattern 130 (FIG. 4) using the third fringe signal calculated from the sum of the first fringe signal F1 (FIG. 6) and the second fringe signal F2 (FIG. 8).

Accordingly, methods for fabricating a semiconductor device according to some embodiments of the present inventive concept are capable of precisely controlling the widths of the upper surfaces of the respective mold layers having a stepped structure by precisely controlling the etched thickness t2 (FIG. 5) of the side surface of the first photoresist pattern 130 (FIG. 4).

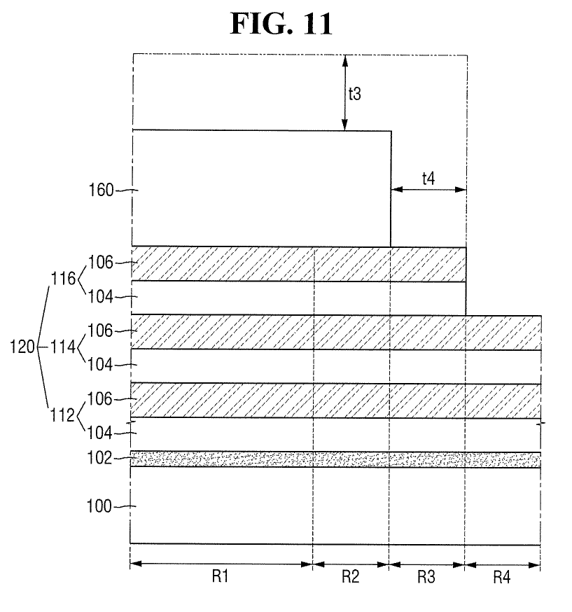

Hereinafter, methods for fabricating a semiconductor device according to some embodiments of the present inventive concept will be described with reference to FIGS. 11 through 14. In the interest of brevity, details discussed above with respect to FIGS. 1 through 10 will not be repeated herein. Accordingly, mainly the differences from the method for fabricating the semiconductor device shown in FIGS. 2 through FIG. 10 will be discussed.

Referring to FIG. 11, after the process according to FIGS. 2 to 4 is performed, the upper surface and the side surface of the first photoresist pattern 130 (FIG. 4) are etched to the same thickness, thereby forming a fourth photoresist pattern 160.

The fourth photoresist pattern 160 may be formed so as to overlap the first and second regions R1 and R2 of the substrate 100. This may result in exposure of the upper surface of the third mold layer 116 of the stacked structure 120 formed on the third region R3 of the substrate.

A third etched thickness t3 of the upper surface of the first photoresist pattern 130 (FIG. 4) may be equal to a fourth etched thickness t2 of the side surface of the first photoresist pattern 130 (FIG. 4).

The third etched thickness t3 and the fourth etched thickness t4 are equal to each other because the etch rate of the upper surface of the first photoresist pattern 130 (FIG. 4) and the etch rate of the side surface of the first photoresist pattern 130 (FIG. 4) are equal to each other.

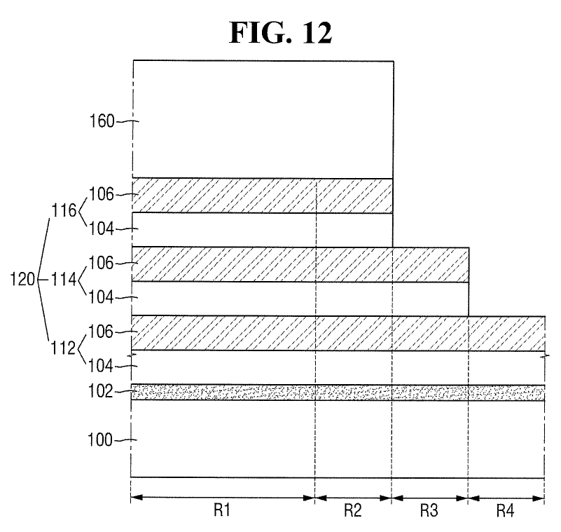

Referring to FIG. 12, using the fourth photoresist pattern 160 as a mask, the third mold layer 116 overlapping the third region R3 of the substrate 100, and the second mold layer 114 overlapping the fourth region R4 of the substrate 100 may be etched, respectively.

This may result in exposure of the upper surface of the second mold layer 114 on the third region R3 of the substrate 100, and the upper surface of the first mold layer 112 on the fourth region R4 of the substrate 100, respectively. Through this etching process, a stepped structure may be formed.

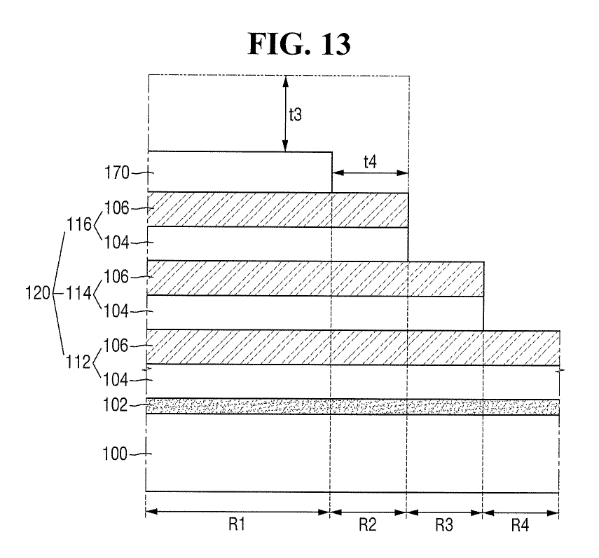

Referring to FIG. 13, a portion of the upper surface and a portion of the side surface of the fourth photoresist pattern 160 (FIG. 12) may be etched to the same thickness to thus form a fifth photoresist pattern 170.

The fifth photoresist pattern 160 may be formed so as to overlap the first region R1 of the substrate 100. This may result in exposure of the upper surface of the third mold layer 116 of the stacked structure 120 formed on the second region R2 of the substrate.

A third etched thickness t3 of the upper surface of the fourth photoresist pattern 160 (FIG. 12) may be equal to a fourth etched thickness t4 of the side surface of the fourth photoresist pattern 160 (FIG. 12).

The third etched thickness t3 and the fourth etched thickness t4 are equal to each other because the etch rate of the upper surface of the fourth photoresist pattern 160 (FIG. 12) and the etch rate of the side surface of the fourth photoresist pattern 160 (FIG. 12) are equal to each other.

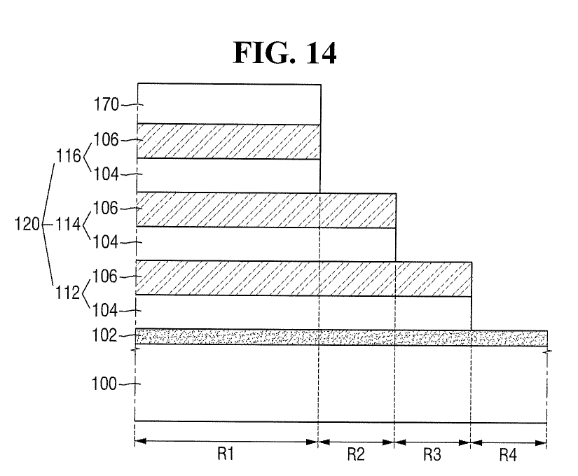

Referring to FIG. 14, using the fifth photoresist pattern 170 as a mask, the third mold layer 116 overlapping the second region R2 of the substrate 100, the second mold layer 114 overlapping the third region R3 of the substrate 100, and the first mold layer 112 overlapping the fourth region R4 of the substrate 100 may be etched, respectively.

This may result in exposure of the upper surface of the second mold layer 114 on the second region R2 of the substrate 100, the upper surface of the first mold layer 112 on the third region R3 of the substrate 100, and the upper surface of the impurity region 102 on the fourth region R4 of the first region R4, respectively. Through this etching process, a stepped structure may be formed.

Exemplary embodiments according to the present inventive concept were explained hereinabove with reference to the drawings attached, but it should be understood that embodiments of the present inventive concept are not limited to the aforementioned embodiments, but may be fabricated in various different forms, and may be implemented by a person skilled in the art in other specific forms without altering the disclosure or characteristics of the present disclosure. Accordingly, it will be understood that the embodiments described above are only illustrative, and should not be construed as limiting.

What is claimed is:

1. A method for fabricating a semiconductor device, the method comprising:
forming a stacked structure, the stacked structure including a first mold layer and a second mold layer sequentially stacked on a substrate;
forming a first photoresist pattern on the stacked structure;
etching the second mold layer using the first photoresist pattern as a mask;
forming a second photoresist pattern by etching a portion of the first photoresist pattern;
measuring a first fringe signal generated by an interference phenomenon between first reflected lights reflected from the first photoresist pattern;
forming a stepped structure by etching the second mold layer and the first mold layer which is exposed, using the second photoresist pattern as a mask;
measuring a second fringe signal generated by an interference phenomenon between second reflected lights reflected from the second mold layer;
calculating a third fringe signal by summing the first fringe signal and the second fringe signal;
calculating a first etch rate of an upper surface of the first photoresist pattern using the third fringe signal;
calculating a second etch rate of a side surface of the first photoresist pattern using the first etch rate; and
controlling a degree of etching the side surface of the second photoresist pattern using the second etch rate.

2. The method of claim 1:
wherein measuring the first fringe signal is performed simultaneously during the etching of the portion of the first photoresist pattern; and
wherein measuring the second fringe signal is performed simultaneously during the forming of the stepped structure by etching the first mold layer and the second mold layer.

3. The method of claim 1, wherein calculating the third fringe signal comprises calculating a number of fringe cycles of the third fringe signal by summing a number of fringe cycles of the first fringe signal and a number of fringe cycles of the second fringe signal.

4. The method of claim 3, wherein the calculating the first etch rate comprises calculating the first etch rate using a predetermined ratio of an etched thickness of the upper surface of the first photoresist pattern to the number of fringe cycles of the third fringe signal.

5. The method of claim 1, wherein the calculating the second etch rate comprises calculating the second etch rate using a predetermined ratio of the first etch rate to the second etch rate.

6. The method of claim 1, wherein the first etch rate is equal to the second etch rate.

7. The method of claim 1, wherein the first etch rate is different from the second etch rate.

8. The method of claim 7, wherein the first etch rate is less than the second etch rate.

9. The method of claim 1, wherein the etching the portion of the first photoresist pattern comprises etching a portion of the upper surface and a portion of the side surface of the first photoresist pattern using plasma.

10. The method of claim 1, wherein each of the first mold layer and the second mold layer comprises a first sacrificial layer comprising silicon nitrides and a second sacrificial layer comprising silicon oxides.

11. A method for fabricating a semiconductor device, the method comprising:
providing a substrate including a first region, a second region and a third region;
forming a stacked structure, the stacked structure including a first mold layer and a second mold layer sequentially stacked on the substrate;
forming a photoresist pattern on the stacked structure to overlap the first region and the second region;
etching the second mold layer formed on the third region using the photoresist pattern as a mask;
etching a portion of an upper surface of the photoresist pattern and the photoresist pattern overlapping the second region;
measuring a first signal using first reflected light reflected from the upper surface of the photoresist pattern while the portion of the upper surface of the photoresist pattern is being etched;
etching the second mold layer formed on the second region and the first mold layer formed on the third region, using the etched photoresist pattern overlapping the first region as a mask;
measuring a second signal using second reflected light reflected from the second mold layer while the second mold layer formed on the second region is being etched;
calculating a third signal by summing the first signal and the second signal;
calculating a first etch rate of the upper surface of the photoresist pattern using the third signal;
calculating a second etch rate of a side surface of the photoresist pattern using the first etch rate; and
controlling a degree of etching the side surface of the photoresist pattern using the second etch rate.

12. The method of claim 11, wherein controlling the degree of etching the side surface of the photoresist pattern using the second etch rate comprises:
adjusting a first etched thickness of the upper surface of the photoresist pattern using the first etch rate; and
determining a second etched thickness of the side surface of the photoresist pattern using the second etch rate.

13. The method of claim 11, wherein a width of the second region is equal to a width of the third region.

14. The method of claim 11, wherein a width of the second region is different from a width of the third region.

15. The method of claim 11:
wherein the first signal is a fringe signal generated by an interference phenomenon between the first reflected lights;
wherein the second signal is a fringe signal generated by an interference phenomenon between the second reflected lights; and
wherein the third signal is a fringe signal calculated by summing the first signal and the second signal.

16. The method of claim 15, wherein calculating the third signal comprises calculating a number of fringe cycles of the third fringe signal by summing a number of fringe cycles of the first fringe signal and a number of fringe cycles of the second fringe signal.

17. A method for fabricating a semiconductor device, the method comprising:
forming a stacked structure, wherein the stacked structure comprises a first mold layer, a second mold layer, and a third mold layer sequentially stacked on a substrate;
forming a first photoresist pattern on the stacked structure;
etching the third mold layer using the first photoresist pattern as a mask;
forming a second photoresist pattern by etching a portion of an upper surface and a portion of a side surface of the first photoresist pattern;
measuring a first fringe signal generated by an interference phenomenon between first reflected lights reflected from the upper surface of the first photoresist pattern while forming the second photoresist pattern;
forming a stepped structure by etching the third mold layer and the second mold layer which is exposed, using the second photoresist pattern as a mask;
measuring a second fringe signal generated by an interference phenomenon between second reflected lights reflected from the third mold layer while the third mold layer is being etched;
calculating a third fringe signal by summing the first fringe signal and the second fringe signal;
calculating a first etch rate of the upper surface of the first photoresist pattern using the third fringe signal;
calculating a second etch rate of the side surface of the first photoresist pattern using the first etch rate;
forming a third photoresist pattern by etching a portion of the upper surface and a portion of the side surface of the second photoresist pattern using the first etch rate and the second etch rate; and
forming a stepped structure by etching the third mold layer, the second mold layer which is exposed, and the first mold layer which is exposed, using the third photoresist pattern.

18. The method of claim 17, wherein an etched thickness of the side surface of the first photoresist pattern is equal to an etched thickness of the side surface of the second photoresist pattern.

19. The method of claim 17, wherein an etched thickness of the side surface of the first photoresist pattern is different from an etched thickness of the side surface of the second photoresist pattern.

20. The method of claim 17, wherein the first etch rate is different from the second etch rate.
